(19) United States
(12) Patent Application Publication
(10) Pub. No.: US 2025/0240872 A1
(43) Pub. Date: Jul. 24, 2025

(54) CIRCUIT BOARD AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Shuang LEI, Beijing (CN); Xu LU, Beijing (CN); An FU, Beijing (CN)

(21) Appl. No.: 18/699,317

(22) PCT Filed: May 5, 2023
(86) PCT No.: PCT/CN2023/092294

§ 371 Date: Apr. 8, 2024

(30) Foreign Application Priority Data
May 7, 2022 (CN) 202210494291.9

(51) Int. Cl. H05K 1/02; H05K 1/03; H05K 1/11; H05K 1/18

(52) U.S. Cl. CPC H05K 1/0218; H05K 1/0393; H05K 1/111; H05K 1/181; H05K 2201/0715; H05K 2201/0723; H05K 2201/0753

(57) ABSTRACT

A circuit board, comprising a thinned area and a non-thinned area, wherein the non-thinned area comprises a first electromagnetic shielding layer, a first composite structure layer and a substrate layer, which are sequentially stacked; the first composite structure layer comprises a first sub-structure layer and a second sub-structure layer which are sequentially stacked in a direction away from the substrate layer, and the first sub-structure layer and the second sub-structure layer each comprises at least one circuit layer; the thinned area comprises a third electromagnetic shielding layer, a first substructure layer and a substrate layer, which are sequentially stacked; an insulating material is provided at the junction of the thinned area and the non-thinned area, and the insulating material isolates the circuit layer in the second substructure layer from the third electromagnetic shielding layer.

### CROSS-REFERENCE TO RELATED APPLICATION

The present application is a U.S. National Phase Entry of International Application No. PCT/CN2023/092294 having an international filing date of May 5, 2023, which claims priority to Chinese patent application No. 202210494291.9, filed to CNIPA on May 7, 2022 and entitled “Circuit Board and Display Apparatus”. Contents of the above-identified applications should be interpreted as being hereby incorporated by reference.

### TECHNICAL FIELD

Embodiments of the present disclosure relate to, but are not limited to, the technical field of circuit boards, and in particular to a circuit board and a display apparatus.

### BACKGROUND

At present, the design functions of mobile phones are becoming more and more abundant, which puts forward higher requirements for the complete machine space. In some technologies, due to the limited space of the complete machine, it is necessary to thin a local area of a flexible printed circuit board (FPC) of a mobile phone for designing other devices. The thinned area of FPC will be attached with an electromagnetic shielding (EMI) film after removing at least one copper layer. Due to the attachment accuracy and process problems, the EMI film in the thinned area will be connected with the copper in the surrounding non-thinned area, resulting in short circuit. In addition, since there is a thickness difference between the thinned area and the non-thinned area, a junction between the thinned area and the non-thinned area is not covered by EMI film, which may cause electromagnetic leakage and lead to electromagnetic interference, and may cause stress concentration at the junction between the thinned area and the non-thinned area during the bending of FPC, resulting in a problem of wiring breakage.

### SUMMARY

The following is a summary of subject matters described herein in detail. This summary is not intended to limit the protection scope of the claims.

An embodiment of the present disclosure provides a circuit board, including a main body portion, wherein the main body portion includes a thinned area and a non-thinned area; the non-thinned area includes a first electromagnetic shielding layer, a first composite structure layer, a substrate layer, a second composite structure layer and a second electromagnetic shielding layer which are sequentially stacked; the second composite structure layer includes at least one circuit layer.

The first composite structure layer includes a first sub-structure layer and a second sub-structure layer that are sequentially stacked in a direction away from the substrate layer, the first sub-structure layer and the second sub-structure layer each including at least one circuit layer; the thinned area includes a third electromagnetic shielding layer, a first substructure layer, a substrate layer, a second composite structure layer and a second electromagnetic shielding layer which are sequentially stacked; an insulating material is provided between the second substructure layer and the third electromagnetic shielding layer at a junction of the thinned area and the non-thinned area, and the insulating material isolates the circuit layer of the second substructure layer from the third electromagnetic shielding layer.

Alternatively, the first composite structure layer includes at least one circuit layer; the thinned area includes a third electromagnetic shielding layer, a substrate layer, a second composite structure layer and a second electromagnetic shielding layer which are sequentially stacked; an insulating material is provided between the first composite structure layer and the third electromagnetic shielding layer at the junction of the thinned area and the non-thinned area, and the insulating material isolates the circuit layer of the first composite structure layer from the third electromagnetic shielding layer.

An embodiment of the present disclosure further provides a display apparatus including the circuit board described above.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic diagram of a partial structure of a circuit board according to some exemplary embodiments;

FIG. 2 is a schematic diagram of a cross-sectional structure taken along A-A of FIG. 1 in some techniques;

FIG. 3a is a schematic diagram of a cross-sectional structure taken along A-A in FIG. 1 according to some exemplary embodiments;

FIG. 3b is a schematic diagram of a cross-sectional structure taken along A-A of FIG. 1 in some other exemplary embodiments; and

FIG. 4 is a schematic diagram of a cross-sectional structure taken along B-B in FIG. 1 in some exemplary embodiments.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

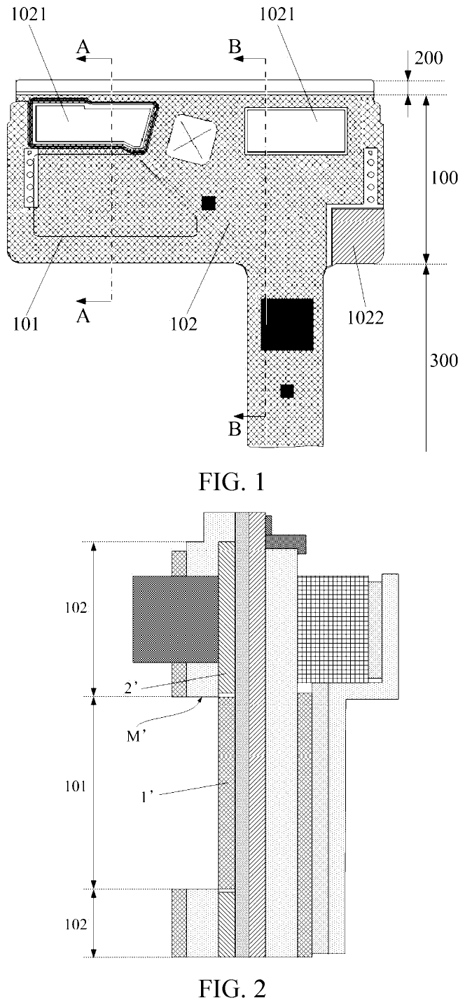

As shown in FIG. 1, FIG. 1 is a schematic diagram of a partial structure of a circuit board according to some exemplary embodiments. Exemplarily, the circuit board may include a main body portion 100, a bonding portion 200 and an extension portion 300. The main body portion 100 may include a first side and a second side opposite to each other, the bonding portion 200 may be disposed at the first side of the main body portion 100, and the extension portion 300 may be disposed at the second side of the main body portion 100. The bonding portion 200 may be provided with a bonding pad configured to be bonded and connected to a first external circuit, and a length direction of the bonding portion 200 may be parallel to an extension direction of the first side of the main body portion 100. The extension portion 300 extends in a direction away from the main body portion 100, and an end of the extension portion 300 away from the main body portion 100 may be configured to be connected to a second external circuit. The main body portion 100 may be provided with an electronic component area 1021. In this example, the shapes of the main body portion 100, the bonding portion 200, and the extension portion 300 are all substantially rectangular. In other embodiments, the shapes of the main body portion 100, the bonding portion 200, and the extension portion 300 may be designed to other regular or irregular shapes according to actual requirements. In order to save the overall space of the electronic device, the main body portion 100 of the circuit board may be provided with a thinned area 101 for designing other devices.

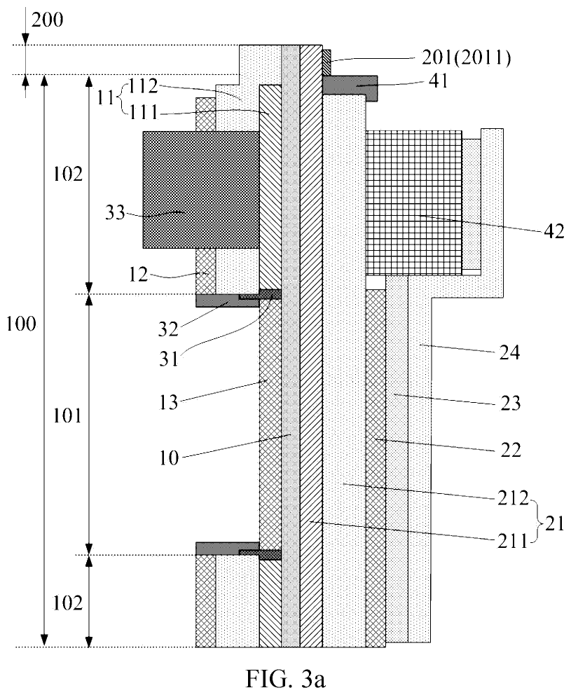

As shown in FIG. 2, FIG. 2 is a schematic diagram of a cross-sectional structure taken along A-A in FIG. 1 in some techniques. In some techniques, an electromagnetic shielding (EMI) film 1′ is attached to the thinned area 101 of the circuit board after at least one copper layer (i.e., a circuit layer) is removed. Due to the attachment accuracy and process problems, the EMI film 1′ of the thinned area 101 is connected with a copper layer 2′ of the surrounding non-thinned area 102, resulting in short circuit. In addition, since there is a thickness difference between the thinned area 101 and the non-thinned area 102, a junction M′ between the thinned area 101 and the non-thinned area 102 is not covered by the EMI film 1′, which may cause electromagnetic leakage and lead to electromagnetic interference, and may cause stress concentration at the junction M′ of the thinned area 101 and the non-thinned area 102 during the bending of FPC, resulting in a problem of wiring breakage.

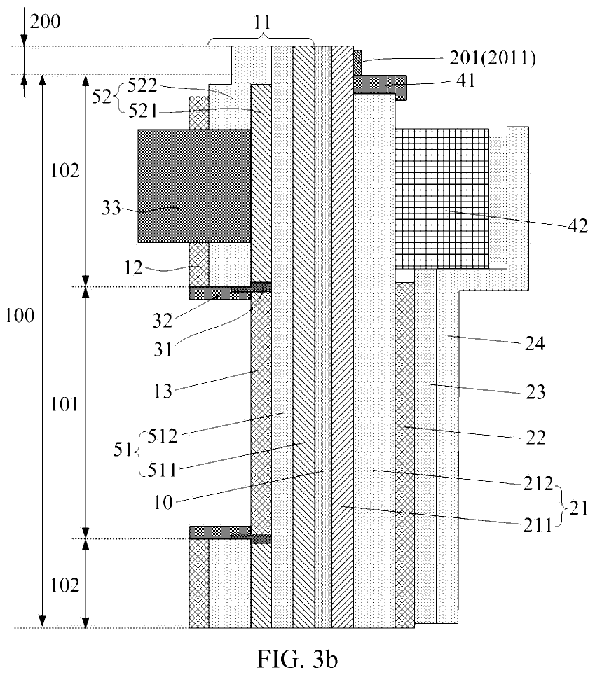

An embodiment of the present disclosure provides a circuit board. In some exemplary embodiments, as shown in FIG. 3a, which is a schematic diagram of a cross-sectional structure taken along A-A in FIG. 1 in some exemplary embodiments, the circuit board includes a main body portion 100 including a thinned area 101 and a non-thinned area 102. The non-thinned area 102 includes a first electromagnetic shielding layer 12, a first composite structure layer 11, a substrate layer 10, a second composite structure layer 21 and a second electromagnetic shielding layer 22 which are sequentially stacked. The second composite structure layer 21 includes at least one circuit layer. The first composite structure layer 11 includes at least one circuit layer. The thinned area 101 includes a third electromagnetic shielding layer 13, a substrate layer 10, a second composite structure layer 21 and a second electromagnetic shielding layer 22 which are sequentially stacked. An insulating material 31 is provided between the first composite structure layer 11 and the third electromagnetic shielding layer 13 at a junction of the thinned area 101 and the non-thinned area 102, and the insulating material 31 isolates the circuit layer of the first composite structure layer 11 from the third electromagnetic shielding layer 13.

In the circuit board of an embodiment of the present disclosure, the first composite structure layer 11 is completely removed at the thinned area 101, an insulating material 31 is provided between the first composite structure layer 11 and the third electromagnetic shielding layer 13 at the junction of the thinned area 101 and the non-thinned area 102, and the insulating material 31 isolates the circuit layer of the first composite structure layer 11 from the third electromagnetic shielding layer 13. Thus, at the junction of the thinned area 101 and the non-thinned area 102, a short circuit problem caused by the connection between the third electromagnetic shielding layer 13 of the thinned area 101 and the circuit layer of the first composite structure layer 11 of the non-thinned area 102 can be prevented.

In some exemplary embodiments, the circuit board may be a flexible circuit board. The total number of circuit layers (also called the total number of layers) of the main body portion may be unlimited, and may be two, three, four, six, etc. Two adjacent circuit layers are separated by an insulating layer. The first composite structure layer and the second composite structure layer may each include one or more circuit layers. The substrate layer may be a base material layer for directly arranging a circuit layer, or may be an adhesive layer for adhesion. The material of the substrate layer may be polyimide (PI), polyethylene terephthalate (PET) or the like. The material of the circuit layer may be copper.

In some exemplary embodiments, as shown in FIG. 3a, the first composite structure layer 11 includes a fourth substructure layer 111 and a first cover layer 112 that are sequentially stacked on the substrate layer 10 in a direction away from the substrate layer 10. The first electromagnetic shielding layer 12 is disposed on a surface of the first cover layer 112 away from the substrate layer 10. In a direction perpendicular to the substrate layer 10, a thickness of the insulating material 31 is d1, and a thickness of the fourth substructure layer 111 is d3, d1>d3. Thus, the insulating material 31 may completely isolate the entire circuit layer(s) of the first composite structure layer 11 of the non-thinned area 102 from the third electromagnetic shielding layer 13 of the thinned area 101.

In some implementations of the present embodiment, the fourth substructure layer 111 may include one or more circuit layers, and in this example, the fourth substructure layer 111 includes one circuit layer as an example. As shown in FIG. 3a, the circuit board is a double-layer circuit board, the total number of circuit layers of the main body portion 100 is two, and the first composite structure layer 11 and the second composite structure layer 21 each include one circuit layer. The fourth substructure layer 111 is a first circuit layer. The second composite structure layer 21 may include a second circuit layer 211 disposed on a second surface of the substrate layer 10 and a second cover layer 212 disposed on a side of the second circuit layer 211 away from the substrate layer 10. The second electromagnetic shielding layer 22 is disposed on a surface of the second cover layer 212 away from the substrate layer 10. In the thinned area 101, all the film layers of the first composite structure layer 11 are removed, and the thinned area 101 includes a third electromagnetic shielding layer 13, a substrate layer 10, a second composite structure layer 21 and a second electromagnetic shielding layer 22 which are sequentially stacked. The third electromagnetic shielding layer 13 is disposed on a first surface of the substrate layer 10. An insulating material 31 is provided between the fourth substructure layer 111 and the third electromagnetic shielding layer 13 at the junction of the thinned area 101 and the non-thinned area 102, and the insulating material 31 isolates the fourth substructure layer 111 from the third electromagnetic shielding layer 13. In order to ensure the isolation effect, the insulating material 31 is also partially disposed on an end face of the first cover layer 112 facing the thinned area 101, that is, in a direction perpendicular to the substrate layer 10, the thickness d1 of the insulating material 31 is greater than the thickness d3 of the fourth substructure layer 111.

Exemplarily, as shown in FIG. 3a, the insulating material 31 may be insulating glue. The material of the substrate layer 10 may be polyimide (PI) or polyethylene terephthalate (PET) or the like, and the thickness of the substrate layer 10 may be from 20 microns to 30 microns, such as 25 microns. The thickness of the fourth substructure layer 111 (first circuit layer) and the second circuit layer 211 may be about 15 microns to 25 microns such as 20 microns. The thickness of the first cover layer 112 and the second cover layer 212 may be about 20 microns to 30 microns, such as 25 microns, and the first cover layer 112 and the second cover layer 212 may each include a PI layer and an adhesive layer. The thickness of the first electromagnetic shielding layer 12, the third electromagnetic shielding layer 13, and the second electromagnetic shielding layer 22 may be about 10 microns to 15 microns, such as 12 microns.

In an example of the present embodiment, as shown in FIG. 3a, at the junction of the thinned area 101 and the non-thinned area 102, an edge of the fourth substructure layer 111 may be provided to retract inwardly relative to an edge of the first cover layer 112 and an edge of the first electromagnetic shielding layer 12. Thus, at the junction of the thinned area 101 and the non-thinned area 102, it is ensured that the first cover layer 112 and the first electromagnetic shielding layer 12 completely cover the circuit layer of the fourth substructure layer 111, and more insulating material 31 can be filled at the inwardly retracted edge of the fourth substructure layer 111, thereby improving the insulating effect.

In an example of the present embodiment, as shown in FIG. 3a, the edge of the first cover layer 112 and the edge of the first electromagnetic shielding layer 12 may be flush at the junction of the thinned area 101 and the non-thinned area 102.

In some exemplary embodiments, as shown in FIG. 3a, at the junction of the thinned area 101 and the non-thinned area 102, an end face of the first composite structure layer 11 facing the thinned area 101 is provided with a conductive material 32, which connects the first electromagnetic shielding layer 12 and the third electromagnetic shielding layer 13. Thus electromagnetic wave leakage at the junction of the thinned area 101 and the non-thinned area 102 due to the absence of an electromagnetic shielding layer can be avoided.

In an example of the present embodiment, as shown in FIG. 3a, a surface of the first composite structure layer 11 of the non-thinned area 102 away from the substrate layer 10 protrudes from a surface of the third electromagnetic shielding layer 13 of the thinned area 101 away from the substrate layer 10. An end face of a portion of the first composite structure layer 11 of the non-thinned area 102 protruding from the surface of the third electromagnetic shielding layer 13 of the thinned area 101 away from the substrate layer 10 (in the example of FIG. 3a, the first cover layer 112) facing the thinned area 101 is completely covered by the conductive material 32, which is also provided on an end face of the first electromagnetic shielding layer 12 facing the thinned area 101 and the surface of the third electromagnetic shielding layer 13 away from the substrate layer 10. Thus, it can be ensured that at the junction of the thinned area 101 and the non-thinned area 102, the conductive material 32 can completely cover the position where electromagnetic waves may leak, thereby improving the electromagnetic shielding effect.

An embodiment of the present disclosure also provides a circuit board according to another exemplary embodiment. As shown in FIG. 3b, which is a schematic diagram of a cross-sectional structure taken along A-A in FIG. 1 in some other exemplary embodiments, the circuit board includes a main body portion 100 including a thinned area 101 and a non-thinned area 102. The non-thinned area 102 includes a first electromagnetic shielding layer 12, a first composite structure layer 11, a substrate layer 10, a second composite structure layer 21 and a second electromagnetic shielding layer 22 which are sequentially stacked. The second composite structure layer 21 includes at least one circuit layer. The first composite structure layer 11 includes a first substructure layer 51 and a second substructure layer 52 which are sequentially stacked in a direction away from the substrate layer 10. The first substructure layer 51 and the second substructure layer 52 each include at least one circuit layer.

The thinned area 101 includes a third electromagnetic shielding layer 13, a first substructure layer 51, a substrate layer 10, a second composite structure layer 21 and a second electromagnetic shielding layer 22 which are sequentially stacked. An insulating material 31 is provided between the second substructure layer 52 and the third electromagnetic shielding layer 13 at a junction of the thinned area 101 and the non-thinned area 102, and the insulating material 31 isolates the circuit layer of the second substructure layer 52 from the third electromagnetic shielding layer 13.

In a circuit board of an embodiment of the present disclosure, the second substructure layer 52 of the first composite structure layer 11 is completely removed in the thinned area 101, and the first substructure layer 51 is retained in the thinned area 101. At the junction of the thinned area 101 and the non-thinned area 102, an insulating material 31 is provided between the second substructure layer 52 and the third electromagnetic shielding layer 13, and the insulating material 31 isolates the circuit layer of the second substructure layer 52 from the third electromagnetic shielding layer 13. Thus, at the junction of the thinned area 101 and the non-thinned area 102, a short circuit problem caused by the connection between the third electromagnetic shielding layer 13 of the thinned area 101 and the circuit layer of the second substructure layer 52 of the non-thinned area 102 can be prevented.

In some exemplary embodiments, as shown in FIG. 3b, the second substructure layer 52 includes a third substructure layer 521 and a first cover layer 522 that are sequentially stacked on the first substructure layer 51 in a direction away from the substrate layer 10. The first electromagnetic shielding layer 12 is disposed on a surface of the first cover layer 522 away from the substrate layer 10. In a direction perpendicular to the substrate layer 10, a thickness of the insulating material 31 is d1, and a thickness of the third substructure layer 521 is d2, d1>d2. Thus, the insulating material 31 may completely isolate the entire circuit layer(s) of the third substructure layer 521 of the non-thinned area 102 from the third electromagnetic shielding layer 13 of the thinned area 101.

In some implementations of the present embodiment, the first substructure layer 51 and the second substructure layer 52 each include one or more circuit layers, and the third substructure layer 521 includes one or more circuit layers. In this example, the first substructure layer 51 and the second substructure layer 52 each include a circuit layer as an example. As shown in FIG. 3b, in the non-thinned area 102, the first substructure layer 51 includes a first circuit layer 511 and an insulating layer 512 sequentially stacked on the substrate layer 10. The second substructure layer 52 includes a third substructure layer (which may be a third circuit layer) 521 and a first cover layer 522 which are sequentially stacked on the insulating layer 512 in a direction away from the substrate layer 10. The first electromagnetic shielding layer 12 is disposed on a surface of the first cover layer 522 away from the substrate layer 10. The second composite structure layer 21 may include a second circuit layer 211 disposed on a second surface of the substrate layer 10 and a second cover layer 212 disposed on a side of the second circuit layer 211 away from the substrate layer 10. The second electromagnetic shielding layer 22 is disposed on a surface of the second cover layer 212 away from the substrate layer 10. The thinned area 101 includes a third electromagnetic shielding layer 13, a first substructure layer 51, a substrate layer 10, a second composite structure layer 21, and a second electromagnetic shielding layer 22 which are sequentially stacked. At the junction of the thinned area 101 and the non-thinned area 102, an insulating material 31 is provided between the second substructure layer 52 and the third electromagnetic shielding layer 13, and the insulating material 31 isolates the third substructure layer (which may be a third circuit layer) 521 from the third electromagnetic shielding layer 13. In order to ensure the isolation effect, the insulating material 31 is also partially disposed on an end face of the first cover layer 522 facing the thinned area 101, that is, in the direction perpendicular to the substrate layer 10, the thickness d1 of the insulating material 31 is greater than the thickness d2 of the third substructure layer (which may be the third circuit layer) 521.

In an example of the present embodiment, as shown in FIG. 3b, at the junction of the thinned area 101 and the non-thinned area 102, an edge of the third substructure layer 521 may be provided to retract inwardly relative to an edge of the first cover layer 522 and an edge of the first electromagnetic shielding layer 12. Thus, at the junction of the thinned area 101 and the non-thinned area 102, it is ensured that the first cover layer 522 and the first electromagnetic shielding layer 12 completely cover the circuit layer of the third substructure layer 521, and more insulating material 31 can be filled at the inwardly retracted edge of the third substructure layer 521, thereby improving the insulating effect.

In an example of the present embodiment, as shown in FIG. 3b, the edge of the first cover layer 522 and the edge of the first electromagnetic shielding layer 12 may be flush at the junction of the thinned area 101 and the non-thinned area 102.

In some exemplary embodiments, as shown in FIG. 3b, at the junction of the thinned area 101 and the non-thinned area 102, an end face of the first composite structure layer 11 facing the thinned area 101 is provided with a conductive material 32, which connects the first electromagnetic shielding layer 12 and the third electromagnetic shielding layer 13. Thus, electromagnetic wave leakage at the junction of the thinned area 101 and the non-thinned area 102 due to the absence of an electromagnetic shielding layer can be avoided.

In an example of the present embodiment, as shown in FIG. 3b, a surface of the first composite structure layer 11 of the non-thinned area 102 away from the substrate layer 10 protrudes from a surface of the third electromagnetic shielding layer 13 of the thinned area 101 away from the substrate layer 10. An end face of a portion of the first composite structure layer 11 of the non-thinned area 102 protruding from the surface of the third electromagnetic shielding layer 13 of the thinned area 101 away from the substrate layer 10 (in the example of FIG. 3b, the first cover layer 522) facing the thinned area 101 is completely covered by the conductive material 32, which is also provided on an end face of the first electromagnetic shielding layer 12 facing the thinned area 101 and a surface of the third electromagnetic shielding layer 13 away from the substrate layer 10. Thus, it can be ensured that at the junction of the thinned area 101 and the non-thinned area 102, the conductive material 32 can completely cover the position where electromagnetic waves may leak, thereby improving the electromagnetic shielding effect.

In some exemplary embodiments, as shown in FIGS. 3a and 3b, the conductive material 32 may be an elastically deformable conductive material 32, and the conductive material 32 may be a conductive adhesive. When the circuit board is a flexible circuit board and is bent, since there is a thickness difference between the thinned area 101 and the non-thinned area 102, stress concentration will occur at the junction of the thinned area 101 and the non-thinned area 102, resulting in the wiring breakage of the circuit layer. The conductive material 32 is disposed to be elastically deformable, so that the conductive material 32 can play a buffering role during the bending of the flexible circuit board, relieving the stress on the wiring at the junction of the thinned area 101 and the non-thinned area 102, thereby reducing wiring breakage.

In some exemplary embodiments, as shown in FIGS. 1 and 3a, the main body portion 100 may include a first side and a second side opposite to each other, and the circuit board may also include a bonding portion 200 disposed at the first side of the main body portion 100 and an extension portion 300 disposed at the second side of the main body portion 100. The bonding portion 200 is provided with a bonding pad 201 configured to be bonded and connected with a first external circuit, and the length direction of the bonding portion 200 may be parallel to the extension direction of the first side of the main body portion 100. The extension portion 300 extends in a direction away from the main body portion 100 and an end of the extension portion 300 away from the main body portion 100 may be configured to be connected to a second external circuit. In this example, the shapes of the main body portion 100, the bonding portion 200, and the extension portion 300 are all substantially rectangular. In other embodiments, the shapes of the main body portion 100, the bonding portion 200, and the extension portion 300 may be designed to other regular or irregular shapes according to actual requirements.

The main body portion 100 is provided with a thinned area 101, the non-thinned area 102 can surround the thinned area 101, and an orthographic projection area of the non-thinned area 102 on the substrate layer 10 is larger than an orthographic projection area of the thinned area 101 on the substrate layer 10. The shape of the thinned area 101 may be a rectangle, a trapezoid or the like and the shape of the thinned area 101 may be set as required. The non-thinned area 102 is provided with at least one electronic component area 1021.

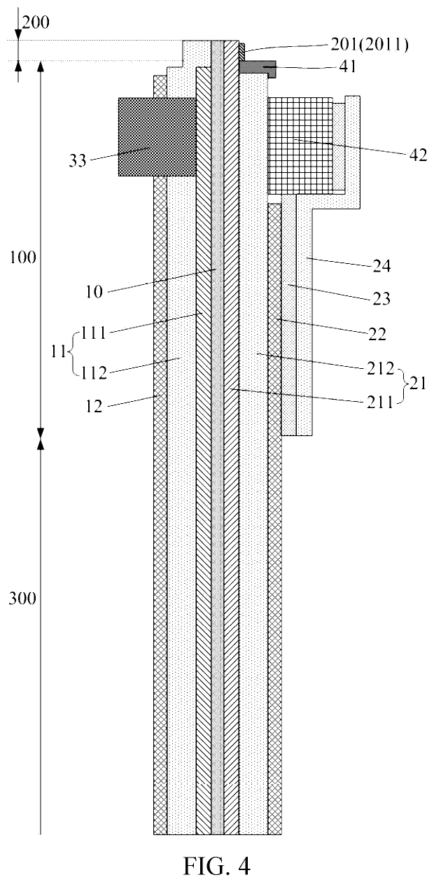

In one example of the present embodiment, as shown in FIGS. 1 and 4, FIG. 4 is a schematic diagram of B-B cross-sectional structure in FIG. 1 in some exemplary embodiments, the schematic diagram of B-B cross-sectional structure of FIG. 4 and the schematic diagram of A-A cross-sectional structure of FIG. 3a may be different schematic diagrams of cross-sectional structure of the circuit board of the same embodiment, and the first electromagnetic shielding layer 12, the first composite structure layer 11, the substrate layer 10, the second composite structure layer 21 and the second electromagnetic shielding layer 22 of the main body portion 100 may all extend to the extension portion 300. The number of circuit layers of the extension portion 300 may be the same as the number of circuit layers of the main body portion 100. In other embodiments, the number of circuit layers of the extension portion 300 may be less than the number of circuit layers of the main body portion 100.

In some exemplary embodiments, as shown in FIG. 3a, the bonding pad 201 may include a first sub-pad portion and a second sub-pad portion 2011 which are stacked, and the first sub-pad portion has a material different from that of the second sub-pad portion 2011. The substrate layer 10 and the at least one circuit layer of the second composite structure layer 21 extend to the bonding portion 200, and one circuit layer of the bonding portion 200 away from the substrate layer 10 is provided with the first sub-pad portion. The second sub-pad portion 2011 is located on a side of the first sub-pad portion away from the substrate layer 10.

Exemplarily, the material of the first sub-pad portion may be the same as a material (e.g. copper) of a circuit layer where the first sub-pad portion is located. The second sub-pad portion 2011 may have a single-layer structure or a multi-layer structure. For example, the second sub-pad portion 2011 may include a nickel layer and a gold layer which are sequentially stacked on the first sub-pad portion. A thickness of the nickel layer may be 2 microns to 4 microns, and a thickness of the gold layer may be 0.03 microns to 0.1 microns (e.g. 0.05 microns). The nickel layer can improve the soldering performance of the bonding pad 201 and the like, and the gold layer can protect the nickel layer from oxidation or corrosion. The nickel layer and the gold layer can be formed by a chemical nickel gold (ENIG) process or an electroplated nickel gold process.

Exemplarily, as shown in FIG. 3a, a surface of the bonding pad 201 away from the substrate layer 10 is lower than a surface of the second composite structure layer 21 of the main body portion 100 away from the substrate layer 10. A gap may be provided between an end face of a film layer of the second composite structure layer 21 of the main body portion 100 that does not extend to the bonding portion 200 facing the bonding portion 200 and the second sub-pad portion 2011, and the gap may be filled with protective glue 41. In a practical application, the circuit board can be a flexible circuit board. After the bonding portion 200 is bent, due to the thickness difference between the bonding portion 200 and the main body portion 100, the flexible circuit board is easy to generate stress concentration at a junction of the bonding portion 200 and the main body portion 100, resulting in the breakage of internal wiring. The protective glue 41 can play a role in buffering stress and preventing wiring breakage.

In some exemplary embodiments, as shown in FIG. 3a, the substrate layer 10 and the at least one circuit layer of the second composite structure layer 21 extend to the bonding portion 200. The bonding pad 201 and the third electromagnetic shielding layer 13 of the thinned area 101 are located on both sides of the substrate layer 10. A surface of the second electromagnetic shielding layer 22 away from the substrate layer 10 may be provided with an adhesive layer 23, and a surface of the adhesive layer 23 away from the substrate layer 10 may be provided with a tearable protective film 24. Exemplarily, a thickness of the adhesive layer 23 and a thickness of the protective film 24 may both be about 0.05 mm. In this embodiment, when the circuit board is used in practice, the protective film 24 can be torn off, and the circuit board can be fixed in the complete machine by the adhesive layer 23.

In some exemplary embodiments, as shown in FIGS. 1 and 3a, the non-thinned area 102 is provided with at least one electronic component area 1021, the electronic component area 1021 is provided with an electronic component 33, and a surface of the at least one electronic component area 1021 facing away from the electronic component 33 is provided with a reinforcing sheet 42. The reinforcing sheet 42 can support and reinforce the local mechanical strength of the circuit board and facilitate the installation of the electronic component 33. The reinforcing sheet 42 may be a stainless steel sheet or the like. A surface of the reinforcing sheet 42 facing away from the substrate layer 10 may be provided with the adhesive layer 23 and the protective film 24.

In some exemplary embodiments, as shown in FIG. 1, the non-thinned area 102 may be provided with a windowed area 1022, and a grounding line of the windowed area 1022 in the first composite structure layer 11 is at least partially exposed. In this way, when the circuit board is applied to the complete machine (such as mobile phone), the circuit board can be connected with a casing of the complete machine by the grounding line to realize the grounding of the circuit board.

An embodiment of the present disclosure further provides a display apparatus, which includes the circuit board according to any one of the previous embodiments. Exemplarily, the display apparatus further includes a display panel with which the circuit board may be bonded and connected. The circuit board can be a flexible circuit board, which is bonded and connected with the display panel by the bonding portion and bent to the back surface of the display panel, and can be connected with a main control board in the complete machine by the extension portion. The display apparatus may be any product or component with a display function, such as a mobile phone, a tablet computer, a television, a display, a laptop computer, a digital photo frame, and a navigator.

In the accompanying drawings, a size of a constituent element, and a thickness of a layer or a region are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus includes a state in which the angle is above −5° and below 5°. In addition, “perpendicular” refers to a state in which an angle formed by two straight lines is above 80° and below 100°, and thus includes a state in which the angle is above 85° and below 95°.

In the description herein, orientation or position relationships indicated by the terms such as “upper”, “lower”, “left”, “right”, “top”, “inside”, “outside”, “axial”, “tetragonal” and the like are orientation or position relationships shown in the drawings, and are intended to facilitate description of the embodiments of the present disclosure and simplification of the description, but not to indicate or imply that the mentioned structure has a specific orientation or is constructed and operated in a specific orientation, therefore, they should not be understood as limitations on the present disclosure.

In the description herein, unless otherwise specified and defined explicitly, terms “connection”, “fixed connection”, “installation”, and “assembly” should be understood in a broad sense, and, for example, may be a fixed connection, a detachable connection, or an integrated connection. Terms “installation”, “connection”, and “fixed connection” may be a direct connection, an indirect connection through an intermediary, or communication inside two elements. For those ordinarily skilled in the art, meanings of the above terms in the embodiments of the present disclosure may be understood according to situations.

1. A circuit board, comprising a main body portion, wherein the main body portion comprises a thinned area and a non-thinned area; the non-thinned area comprises a first electromagnetic shielding layer, a first composite structure layer, a substrate layer, a second composite structure layer and a second electromagnetic shielding layer which are sequentially stacked; the second composite structure layer comprises at least one circuit layer;
the first composite structure layer comprises a first sub-structure layer and a second sub-structure layer that are sequentially stacked in a direction away from the substrate layer, the first sub-structure layer and the second sub-structure layer each comprising at least one circuit layer; the thinned area comprises a third electromagnetic shielding layer, a first substructure layer, a substrate layer, a second composite structure layer and a second electromagnetic shielding layer which are sequentially stacked; an insulating material is provided between the second substructure layer and the third electromagnetic shielding layer at a junction of the thinned area and the non-thinned area, and the insulating material isolates the circuit layer of the second substructure layer from the third electromagnetic shielding layer;
or, the first composite structure layer comprises at least one circuit layer; the thinned area comprises a third electromagnetic shielding layer, a substrate layer, a second composite structure layer and a second electromagnetic shielding layer which are sequentially stacked; an insulating material is provided between the first composite structure layer and the third electromagnetic shielding layer at the junction of the thinned area and the non-thinned area, and the insulating material isolates the circuit layer of the first composite structure layer from the third electromagnetic shielding layer.

2. The circuit board according to claim 1, wherein the second substructure layer comprises a third substructure layer and a first cover layer that are sequentially stacked on the first substructure layer in the direction away from the substrate layer, and the first electromagnetic shielding layer is disposed on a surface of the first cover layer away from the substrate layer;
in a direction perpendicular to the substrate layer, a thickness of the insulating material is d1, and a thickness of the third substructure layer is d2, d1>d2.

3. The circuit board according to claim 1, wherein the thinned area comprises a third electromagnetic shielding layer, a substrate layer, a second composite structure layer and a second electromagnetic shielding layer which are sequentially stacked;
the first composite structure layer comprises a fourth substructure layer and a first cover layer which are sequentially stacked on the substrate layer in the direction away from the substrate layer, and the first electromagnetic shielding layer is disposed on a surface of the first cover layer away from the substrate layer;
in a direction perpendicular to the substrate layer, a thickness of the insulating material is d1, and a thickness of the fourth substructure layer is d3, d1>d3.

4. The circuit board according to claim 2, wherein at the junction of the thinned area and the non-thinned area, an edge of the third substructure layer is provided to retract inwardly with respect to an edge of the first cover layer and an edge of the first electromagnetic shielding layer.

5. The circuit board according to claim 3, wherein at the junction of the thinned area and the non-thinned area, an edge of the fourth substructure layer is provided to retract inwardly with respect to an edge of the first cover layer and an edge of the first electromagnetic shielding layer.

6. The circuit board according to claim 4, wherein the edge of the first cover layer and the edge of the first electromagnetic shielding layer are flush at the junction of the thinned area and the non-thinned area.

7. The circuit board according to claim 1, wherein at the junction of the thinned area and the non-thinned area, an end face of the first composite structure layer facing the thinned area is provided with a conductive material, and the conductive material connects the first electromagnetic shielding layer and the third electromagnetic shielding layer.

8. The circuit board according to claim 7, wherein a surface of the first composite structure layer of the non-thinned area away from the substrate layer protrudes from a surface of the third electromagnetic shielding layer of the thinned area away from the substrate layer;
an end face of a portion of the first composite structure layer of the non-thinned area protruding from the surface of the third electromagnetic shielding layer of the thinned area away from the substrate layer facing the thinned area is completely covered by the conductive material, and the conductive material is also provided on an end face of the first electromagnetic shielding layer facing the thinned area and a surface of the third electromagnetic shielding layer away from the substrate layer.

9. The circuit board according to claim 7, wherein the conductive material is an elastically deformable conductive material.

10. The circuit board according to claim 1, wherein the non-thinned area surrounds the thinned area, and an orthographic projection area of the non-thinned area on the substrate layer is greater than an orthographic projection area of the thinned area on the substrate layer.

11. The circuit board according to claim 1, wherein the main body portion comprises a first side and a second side opposite to each other, and the circuit board further comprises a bonding portion disposed at the first side of the main body portion and an extension portion disposed at the second side of the main body portion;
the bonding portion is provided with a bonding pad configured to be bonded and connected with an external circuit, a length direction of the bonding portion is parallel to a extension direction of the first side of the main body portion, and the extension portion extends in a direction away from the main body portion.

12. The circuit board according to claim 11, wherein the bonding pad comprises a first sub-pad portion and a second sub-pad portion that are stacked, a material of the first sub-pad portion being different from a material of the second sub-pad portion;
the substrate layer and the at least one circuit layer of the second composite structure layer extend to the bonding portion, and one circuit layer of the bonding portion away from the substrate layer is provided with the first sub-pad portion, and the second sub-pad portion is located on a side of the first sub-pad portion away from the substrate layer.

13. The circuit board according to claim 12, wherein a surface of the bonding pad away from the substrate layer is lower than a surface of the second composite structure layer of the main body portion away from the substrate layer, a gap is provided between an end face of a film layer of the second composite structure layer of the main body portion that does not extend to the bonding portion facing the bonding portion and the second sub-pad portion, and the gap is filled with protective glue.

14. The circuit board according to claim 11, wherein the substrate layer and the at least one circuit layer of the second composite structure layer extends to the bonding portion, and the bonding pad and the third electromagnetic shielding layer are positioned on both sides of the substrate layer;
a surface of the second electromagnetic shielding layer away from the substrate layer is provided with an adhesive layer, and a surface of the adhesive layer away from the substrate layer is provided with a tearable protective film.

15. The circuit board according to claim 1, wherein the non-thinned area is provided with at least one electronic component area, the electronic component area is provided with an electronic component, and a surface of the at least one electronic component area facing away from the electronic component is provided with a reinforcing sheet.

16. The circuit board according to claim 1, wherein the non-thinned area is provided with a windowed area, and a grounding line of the windowed area in the first composite structure layer is at least partially exposed.

17. A display apparatus, comprising the circuit board according to claim 1.

18. The circuit board according to claim 5, wherein the edge of the first cover layer and the edge of the first electromagnetic shielding layer are flush at the junction of the thinned area and the non-thinned area.

19. A display apparatus, comprising the circuit board according to claim 2.

20. A display apparatus, comprising the circuit board according to claim 3.
